(19) United States
(12) Patent Application Publication
(10) Pub. No.: US 2026/0129926 A1
(43) Pub. Date: May 7, 2026

(54) BACKSIDE CONTACT STRUCTURE WITHIN RETAINED SUBSTRATE STRUCTURE

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Reinaldo Vega, Mahopac, NY (US)

(21) Appl. No.: 18/934,472

(22) Filed: Nov. 1, 2024

(51) Int. Cl. H01L 29/06; H01L 27/088; H01L 29/10; H01L 29/417; H01L 29/423; H01L 29/66; H01L 29/775; H01L 29/786

(52) U.S. Cl. CPC H10D 62/116; H10D 30/6729; H10D 62/364; H10D 84/83; H10D 30/014; H10D 30/43; H10D 30/6735; H10D 30/6757; H10D 62/121

(57) ABSTRACT

A semiconductor integrated circuit device is described. The device may include a semiconductor base, a source/drain region directly connected to a plurality of channels and directly connected to a portion of a first sidewall of the semiconductor base. The device may further include a backside contact directly connected to the S/D region and directly connected to a remaining portion of the first sidewall of the semiconductor base. The device may further include a backside contact plug directly connected to a second sidewall of semiconductor base. The backside contact plug substantially prevents electrical current from the S/D region through the semiconductor base.

### BACKGROUND

The present disclosure relates to fabrication methods and resulting structures for semiconductor devices. More specifically, the present disclosure relates to fabrication methods and resulting semiconductor integrated circuit (IC) devices that include one or more backside contact structures, such as a backside contact and/or a backside contact plug, within a retained substrate structure.

Conventional transistors, such as semiconductor IC devices, or the like, incorporate planar field effect transistors (FETs) in which current flows through a semiconducting channel between a source and a drain in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET, generally, is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which a majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for improved control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

### SUMMARY

In an embodiment of the present disclosure, a semiconductor integrated circuit (IC) device is presented. The semiconductor IC device includes a semiconductor base that has a first sidewall and a second sidewall. The semiconductor IC device includes a plurality of channels above the semiconductor base and a gate upon the semiconductor base and surrounding each of the plurality of channels. The semiconductor IC device includes a first source/drain (S/D) region directly connected to the plurality of channels and at least partially to the first sidewall of the semiconductor base. The semiconductor IC device includes a second S/D region directly connected to the plurality of channels and a retained semiconductor substrate structure below the semiconductor base. The semiconductor IC device includes a backside contact plug within the retained semiconductor substrate, the backside contact plug in direct contact with the second S/D region, and in direct contact with the second sidewall of the semiconductor base.

In an embodiment of the present disclosure, a semiconductor integrated circuit (IC) device is presented. The semiconductor IC device includes a first transistor and a second transistor. The first transistor includes a semiconductor base, a plurality of channels above the semiconductor base, a gate upon the semiconductor base and surrounding each of the plurality of channels, a first source/drain (S/D) region, and a second S/D region. The second transistor includes a third S/D region adjacent to the second S/D region. The semiconductor IC device further includes a retained semiconductor substrate structure below the semiconductor base and a first backside contact within the retained semiconductor substrate in direct contact with the first S/D region. The semiconductor IC device further includes a backside contact plug within the retained semiconductor substrate and in direct contact with the second S/D region and a second backside contact within the retained semiconductor substrate in direct contact with the third S/D region and in direct contact with the backside contact plug.

In an embodiment of the present disclosure, a semiconductor integrated circuit (IC) device is presented. The semiconductor IC device includes a semiconductor base, a source/drain (S/D) region directly connected to a plurality of channels and directly connected to a portion of a first sidewall of the semiconductor base, a backside contact directly connected to the S/D region and directly connected to a remaining portion of the first sidewall of the semiconductor base, and a backside contact plug directly connected to a second sidewall of semiconductor base. The backside contact plug substantially prevents electrical current from the S/D region through the semiconductor base.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 and FIG. 2 depict cross section views of a semiconductor IC device that includes backside contact structures in a retained substrate structure, according to one or more embodiments of the disclosure.

FIG. 3 depicts a partial structure top-down view of an illustrative semiconductor IC device, according to one or more embodiments of the disclosure.

FIG. 4 through FIG. 12 depict respective cross section fabrication views of a semiconductor IC device that includes or is to include a bottom isolation region between a gate and a backside contact, according to one or more embodiments of the disclosure.

FIG. 13 depicts a flowchart of a method of fabricating a semiconductor IC device that includes a tapered inner spacer, according to one or more embodiments of the disclosure.

### DETAILED DESCRIPTION

The flowcharts and cross-sectional diagrams in the drawings illustrate a method of fabricating semiconductor IC device, such as a processor, filed programmable gate array (FPGA), memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, for some transistor architectures, integration of the transistors with a backside back end of line (BEOL) network is one of the key challenges to providing increasing packaged IC device densities and performance increases. By incorporating the BEOL network into the semiconductor IC device, there may be a logical and/or functional separation between electrical signal routing and electrical power routing through the semiconductor IC device which may ease routing congestion in some applications.

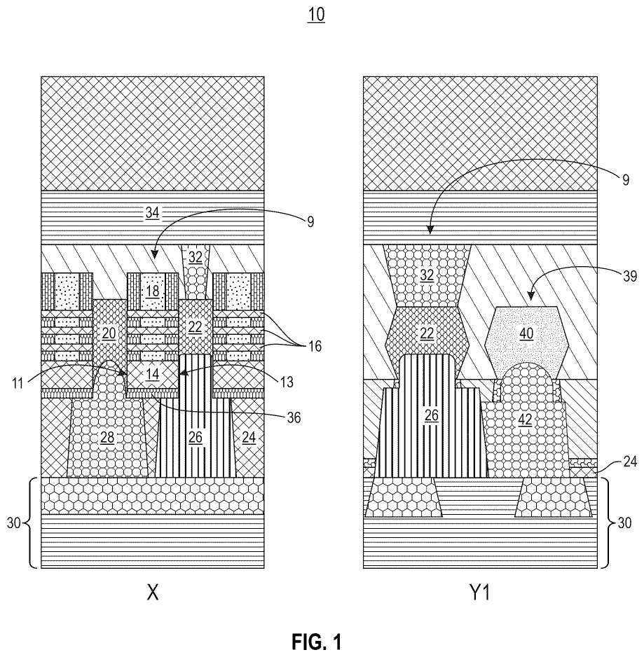

Turing to embodiments of the disclosure and with reference to FIG. 1, a semiconductor IC device 10 is presented that includes a semiconductor base 14 that includes a first sidewall 11 and a second sidewall 13. The semiconductor IC device 10 includes a plurality of channels 16 above the semiconductor base 14. The semiconductor IC device 10 includes a gate 18 upon the semiconductor base 14 and surrounding each of the plurality of channels 16. The semiconductor IC device 10 includes a first source/drain (S/D) region 20 directly connected to the plurality of channels 16 and at least partially to the first sidewall 11 of the semiconductor base 14. The semiconductor IC device 10 includes a second S/D region 22 directly connected to the plurality of channels 16. The semiconductor IC device 10 includes a retained semiconductor substrate structure 24 below the semiconductor base 14. The semiconductor IC device 10 includes a backside contact plug 26 within the retained semiconductor substrate 24. The backside contact plug 26 is in direct contact with the second S/D region 22 and in direct contact with the second sidewall 13 of the semiconductor base 14.

In an example, the backside contact plug 26 substantially prevents electrical current between the first S/D region 20 and the second S/D region 22 through the semiconductor base 14. For example, when there exists electrical current between the first S/D region 20 and the second S/D region 22 through the plurality of channels 16 (e.g., the applicable transistor is “on”), the backside contact plug 26 substantially prevents electrical current between the first S/D region 20 and the second S/D region 22 through the semiconductor base 14.

In an example, a backside surface of the second S/D region 22 is above a frontside surface of the semiconductor base 14. In other words, a frontside surface of the backside contact plug 26 may be above the frontside surface of the semiconductor base 14.

In an example, the semiconductor IC device 10 further includes a backside contact 28 within the retained semiconductor substrate 24 in direct contact with the first S/D region 20. In an example, a frontside surface of the backside contact plug 28 is above a frontside surface of the backside contact 28. In other words, relatively more of the backside of S/D region 22 may be removed or gouged relative to the backside of S/D region 20.

In an example, the plurality of channels 16 are directly connected to the second S/D region 22. In an example, the semiconductor IC device 10 further includes a backside back end of line (BEOL) network 30 that is directly connected to the backside contact 28, directly connected to the backside contact plug 26, and directly connected to the retained semiconductor substrate structure 24.

In an example, the semiconductor IC device 10 further includes a frontside contact 32 directly connected to the second S/D region 22. In an example, the semiconductor IC device 10 further includes a frontside back end of line (BEOL) network 34 directly connected to the frontside contact 32. In an example, the semiconductor IC device 10 further includes a bottom isolation region 36 between the semiconductor base 14 and the retained semiconductor structure 24.

In another embodiment of the present disclosure, another instance of semiconductor IC device 10 is presented. The semiconductor IC device 10 includes a first transistor 9 and a second transistor 39. The first transistor 9 and the second transistor 39 may be opposite type transistors (e.g., n-type and p-type). The first transistor 9 includes the semiconductor base 14, the plurality of channels 16 above the semiconductor base 14, the gate 18 upon the semiconductor base 14 and surrounding each of the plurality of channels 16, the first S/D region 20, and the second S/D region 22. The second transistor 39 includes a third S/D region 40 adjacent to the second S/D region 22. The semiconductor IC device 10 includes the retained semiconductor substrate structure 24 below the semiconductor base 14, a first backside contact (i.e., backside contact 28) within the retained semiconductor substrate 24 and in direct contact with the first S/D region 20. The semiconductor IC device 10 includes the backside contact plug 26 within the retained semiconductor substrate 24 and in direct contact with the second S/D region 22. The semiconductor IC device 10 also includes a second backside contact 42 within the retained semiconductor substrate 24 in direct contact with the third S/D region 40 and in direct contact with the backside contact plug 26.

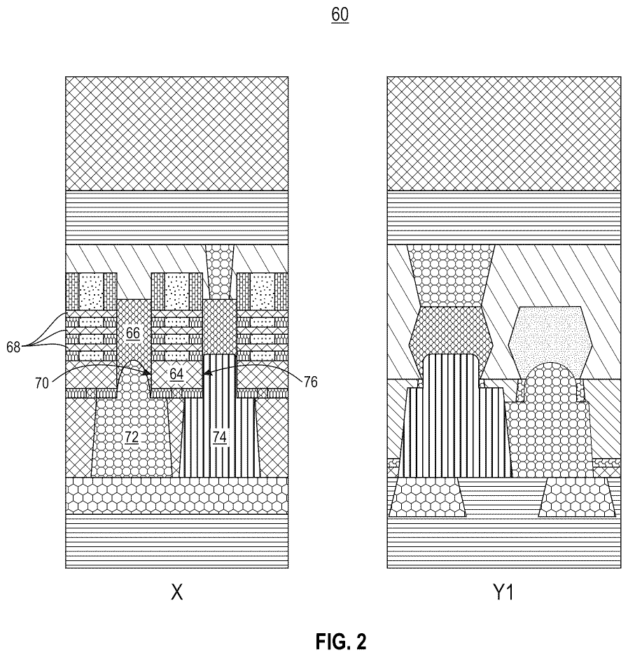

Turing to embodiments of the disclosure and with reference to FIG. 2, a semiconductor IC device 60 is presented. Semiconductor IC device 60 includes a semiconductor base 64, a source/drain (S/D) region 66 directly connected to a plurality of channels 68 and directly connected to a portion of a first sidewall 70 of the semiconductor base 64. Semiconductor IC device 60 includes a backside contact 72 directly connected to the S/D region 66 and directly connected to a remaining portion of the first sidewall 70 of the semiconductor base 64. Semiconductor IC device 60 includes a backside contact plug 74 directly connected to a second sidewall 76 of semiconductor base 64. The backside contact plug 74 substantially prevents electrical current between the S/D region 66 and the backside contact plug 74 through the semiconductor base 64. For example, when there exists electrical current through the plurality of channels 68 due to e.g., the relationship between such channels 68, a gate and the potential applied to the associated S/D regions, the backside contact plug 74 substantially prevents similar associated electrical current through the semiconductor base 64.

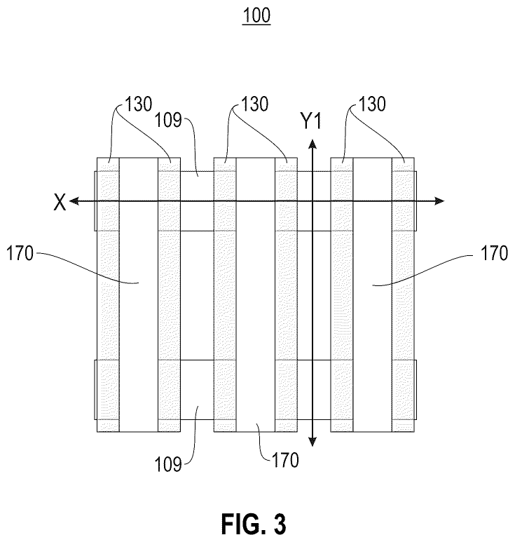

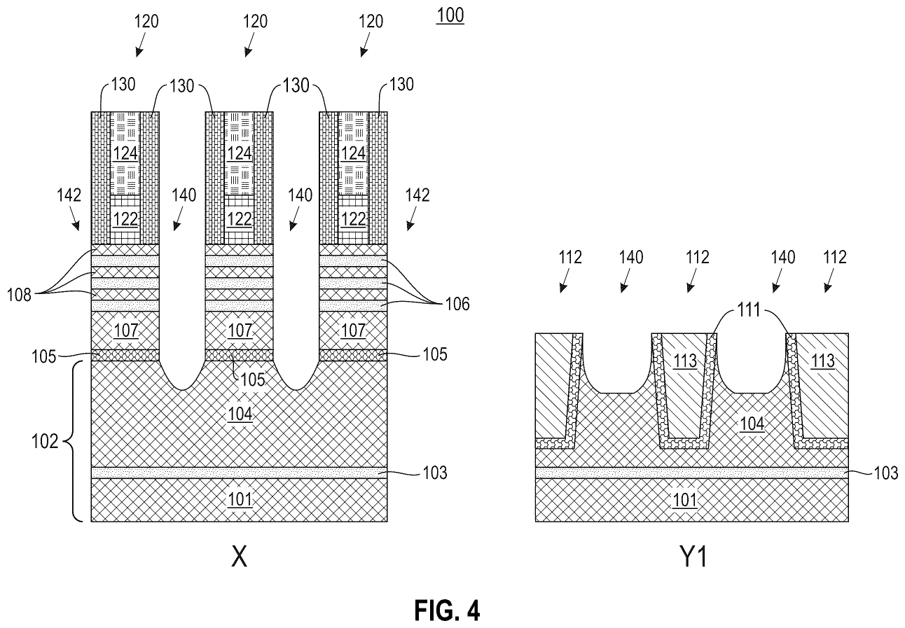

FIG. 3 depicts a partial structure top-down view of an illustrative semiconductor IC device 100, according to one or more embodiments of the disclosure. As currently depicted, semiconductor IC device 100 includes nanolayer rows 109, gate spacers 130, and replacement gate structures 170. FIG. 4 also depicts cross-sectional planes of the various cross-sectional views of at least some of the drawings. The X cross-sectional plane is through a nanolayer row 109 and across replacement gate structures 170. The Y1 cross-sectional plane is through a replacement gate structure 170 and across nanolayer rows 109. The Y2 cross-sectional plane between replacement gate structures 170 and across nanolayer rows 109.

FIG. 4 depicts a cross-sectional view of the semiconductor IC device 100 after initial fabrication operations, in accordance with embodiments of the present disclosure. In these initial fabrication stages, semiconductor IC device 100 may include a substrate structure 102, a lowest sacrificial nanolayer 105, an inactive nanolayer 107, an alternating series of sacrificial nanolayers 106 and active nanolayers 108, shallow trench isolation regions 112, and sacrificial gate structures 120.

For clarity, the term “inactive” is utilized with reference to inactive nanolayer 107 since at least a remnant of inactive nanolayer 107 may not provide for electrical current there through, when associated current exists through the plurality of channels of an associated transistor. Further discussion and meaning and/or context regarding the inactivity of the remnant of inactive nanolayer 107 is included herein.

The illustrated semiconductor IC device 100, at the present fabrication stage, may be formed by GAA FET semiconductor IC device fabrication techniques. These techniques to fabricate the semiconductor IC device 100 may be known or later developed. An illustrative fabrication sequence follows. For clarity, various structures may be referred to in this illustrative fabrication sequence and not enumerated in FIG. 4. When the enumerated elements depicted in FIG. 4 are referred to in this illustrative fabrication sequence their respective numeral is utilized.

The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In another implementation, the substrate structure 102 includes an upper substrate 104, a lower substrate 101, and an insulator layer between the upper substrate and the lower substrate. The upper and lower substrates may be comprised of any other suitable material(s) than those listed above, and the insulator layer may be a dielectric layer, such as an oxide, and may be referred to as a buried oxide (BOX) substrate. In another implementation, as depicted, the substrate structure 102 includes the upper substrate 104, the lower substrate 101, and an etch stop layer 103 between the upper substrate 104 and the lower substrate 101. The etch stop layer 103 may be a dielectric layer and may be any dielectric with etch selectivity to one or both the upper substrate 104 and/or the lower substrate 101.

Nanolayers may be formed upon the substrate structure 102 by forming a lowest sacrificial nanolayer 105 directly on an upper surface of the substrate structure 102 and by forming an inactive nanolayer 107 upon an upper surface of the lowest sacrificial nanolayer 105. Next, alternating blanket layers of sacrificial nanolayers 106 and active nanolayers 108 may be formed.

In an illustrative example, the lowest sacrificial nanolayer 105 is composed of silicon-germanium (e.g., SiGe, where the Ge ranges from about 50-80%). Further, in an illustrative example, each of the sacrificial nanolayers 106 are composed of silicon-germanium (e.g., SiGe, where the Ge ranges from about 20-30%). In this manner, the lowest sacrificial nanolayer 105 may have etch selectivity to the sacrificial nanolayers 106. Still further, in an illustrative example, the inactive nanolayer 107 and the active nanolayers 108 are composed of silicon.

Although it is specifically contemplated that the sacrificial nanolayers 106 and the lowest sacrificial nanolayer 105 can be formed from SiGe and that the inactive nanolayer 107 and active nanolayers 108 can be formed from Si, it should be understood that any appropriate materials can be used instead, as long as the two semiconductor materials have etch selectivity with respect to one another.

In certain embodiments, the sacrificial nanolayers 106, the lowest sacrificial nanolayer 105, and the active nanolayers 108 have a vertical thickness ranging, for example, from approximately 3 nm to approximately 20 nm. Although the range of 3-20 nm is cited as an example range of thickness of the lowest sacrificial nanolayer 105, the sacrificial nanolayers 106 and active nanolayers 108, other thickness of these nanolayers may be used. In certain examples, certain of the lowest sacrificial nanolayer 105, the sacrificial nanolayers 106 and active nanolayers 108 may have different thicknesses relative to one another. The inactive nanolayer 107 have a vertical thickness ranging, for example, from approximately 20 nm to approximately 50 nm. The inactive nanolayer 107 provides enough distance and/or electrical isolation or separation between backside metal contact and nearby (non-connected) source/drain regions.

The nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In a particular embodiment, the lowest sacrificial nanolayer 105 may be epitaxially grown from substrate structure 102, the inactive nanolayer 107 may be epitaxially grown from lowest sacrificial nanolayer 105, and the alternating blanket layers of sacrificial nanolayers 106 and active nanolayers 108 may be epitaxially grown from the inactive nanolayer 107. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

To form one or more nanolayer rows 109, depicted in FIG. 3, a mask layer (not shown) may be formed on the uppermost nanolayer. The mask layer may be comprised of any suitable mask or lithography material(s). The mask layer may be patterned and used to perform the nanolayer row 109 patterning process. In the nanolayer row 109 patterning process, any suitable material removal process (e.g., reactive ion etching or RIE) may be used to remove portions of the alternating nanolayers down to or into the upper substrate 104. As this present fabrication stage, within each nanolayer row 109 there is a lowest sacrificial nanolayer 105, inactive nanolayer 107, and alternating sacrificial nanolayers 106 and active nanolayers 108 formed from the associated nanolayers, respectively. Subsequently, the mask layer may be removed.

The removal of undesired portion(s) of the nanolayers may further remove undesired portions the substrate structure 102 that are adjacent to respective footprints of nanolayer rows 109 to form STI region openings. The etch may be timed or otherwise controlled to stop the removal of the substrate structure 102 such that the depth or bottom of the one or more STI region openings has a predetermined or desired dimension.

A STI region 112 may be formed within the substrate structure 102 below and adjacent to the nanolayer rows 109 within the STI region openings. For example, one or more STI regions 112 may be formed by depositing isolation material within the STI region openings adjacent to the one or more nanolayer rows 109. A top surface of the one or more STI regions 112 may be at or below a top surface of lowest sacrificial nanolayer 105. The STI region(s) 130 may be formed by depositing STI liner 111, such as a nitride, upon the substrate structure 102 and subsequently depositing an STI fill 113, such as an oxide upon the STI liner 111. The one or more STI regions 112 may have a volume that sufficiently electrically isolates components or features of neighboring transistors, or the like, and/or may sufficiently electrically isolate neighboring nanolayer rows 109.

The sacrificial gate structures 120 may be formed by initially depositing the sacrificial gate liner layer (e.g., a dielectric, oxide, or the like) upon the one or more STI regions 112 and upon and around the one or more nanolayer rows 109. The sacrificial gate structures 120 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 109. The sacrificial gate structures 120 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 120 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 122, and the sacrificial gate cap 124, respectively, of each of the one or more sacrificial gate structures 120.

The gate spacer(s) 130 may be respectively formed upon the one or more STI regions 112, upon and around the one or more nanolayer rows 109, and upon and around each of the one or more sacrificial gate structures 120. In one example, gate spacers 130 may be formed of a dielectric material(s), such as such as silicon nitride, SiBCN, SiNC, SiN, SiCO, SiNOC, a combination thereof, or the like.

The one or more gate spacers 130 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures 120 intact.

The one or more S/D canyons 140 may be formed between adjacent sacrificial gate structures 120 by removing respective portions of the sacrificial nanolayers 106 and active nanolayers 108 that are between gate spacers 130 of adjacent or neighboring sacrificial gate structures 120. The one or more S/D canyons 140 may be formed to a depth to stop at or within the upper substrate 104. The nanolayers may be removed by one or more etches that may be selective to the respective material(s) of gate spacers 130, sacrificial gate cap 124, and/or STI regions 112.

The retained one or more portions of one or more nanolayer rows 109 may be such portions of the nanolayers that were protected generally below and/or internal to respective sacrificial gate structures 120 and/or by the associated gate spacers 130 and may be referred to herein as nanolayer stacks 142. As such, as is depicted, respective sidewalls or end surfaces of the nanolayer stacks 142 may be coplanar with respective outer sidewalls of the associated gate spacers 130.

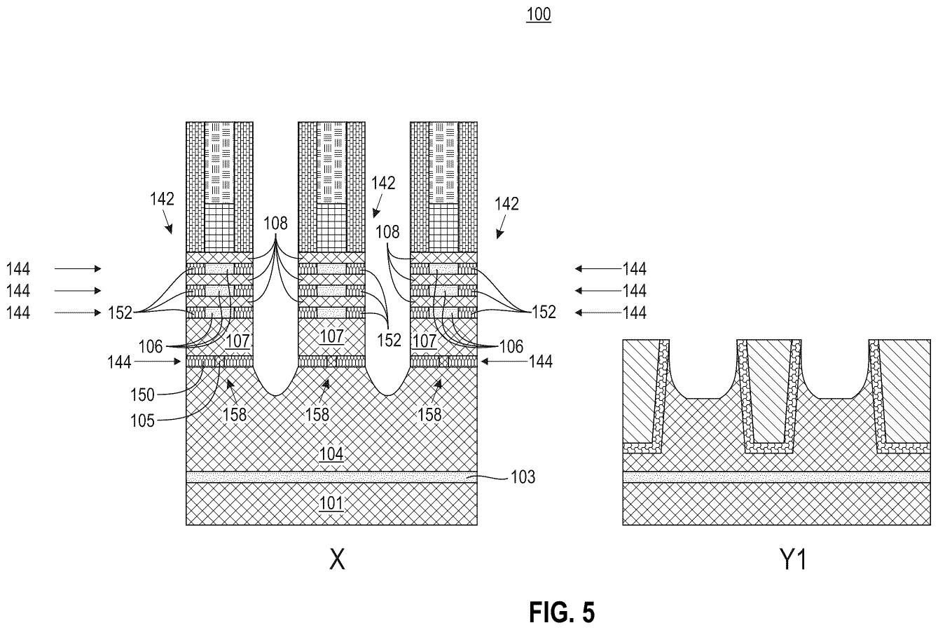

FIG. 5 depicts a cross-sectional view of the semiconductor IC device 100 after fabrication operations, in accordance with embodiments of the present disclosure. In the depicted fabrication stages, indents 144 may be formed within the lowest sacrificial nanolayer 105 by removing respective all or portions of the lowest sacrificial nanolayer 105 within the nanolayer stack(s) 142 and indents 144 may be formed within the sacrificial nanolayer 106 by removing portions of the sacrificial nanolayers 106 within the nanolayer stack(s) 142.

Indents 144 may be formed by a reactive ion etch (RIE) process and/or a wet etch process, which can remove portions (or all) of the lowest sacrificial nanolayer 105 and which can remove portions of the sacrificial nanolayers 106. The etch may be selective to the active nanolayers 108, to the inactive nanolayer 107, to the upper substrate 104, to the STI region 112, to the gate spacers 130, to the sacrificial gate cap 124, and/or the like.

The etch may consume all of or a portion of the lowest sacrificial nanolayer 105. For example, in embodiments where the bottom isolation region is to be located under all of the nanolayer stack(s) 142 (depicted for example in FIG. 1), all of the lowest sacrificial nanolayer 105 may be removed. In alternative embodiments in which the bottom isolation region is bifurcated under the nanolayer stack(s) 142 (depicted for example in FIG. 2), only portion(s) of the lowest sacrificial nanolayer 105 may be removed while a residual portion of the sacrificial nanolayer 105 remains. The etch can be controlled to remove the portions of the sacrificial nanolayers 106 not covered by the sacrificial gate 122. For example, the horizontal depth of the indents 144 may be chosen to set a gate length for a replacement gate structure that is formed in place of one sacrificial gate structure 120. When both the sacrificial nanolayers 106 and the lowest sacrificial nanolayer 105 are SiGe, due to the relatively higher Germanium percentage within lowest sacrificial nanolayer 105 the etch that forms indents 144 may horizontally remove relatively more of the lowest sacrificial nanolayer 105 compared to the sacrificial nanolayers 106.

Subsequently, the indents 144 may be filled by depositing a dielectric which may resultantly form respective lower spacers 150 between the inactive nanolayer 107 and the substrate structure 102 and may resultantly form the respective inner spacers 152 against the active nanolayers 108. In the examples, where all of the lowest sacrificial nanolayer 105 is removed by the indents 144, the lower spacers 150 may fill the void between the inactive nanolayer 107 and the substrate structure 102. In the examples, some of the lowest sacrificial nanolayer 105 is retained by the indents 144, a sandwich of the retained portion of the lowest sacrificial nanolayer 105 between the lower spacers 150 may fill the void between the inactive nanolayer 107 and the substrate structure 102, as depicted.

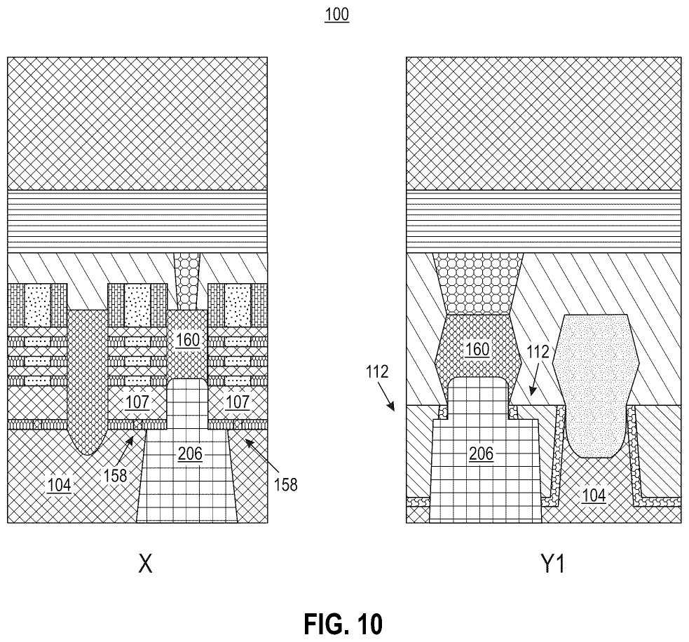

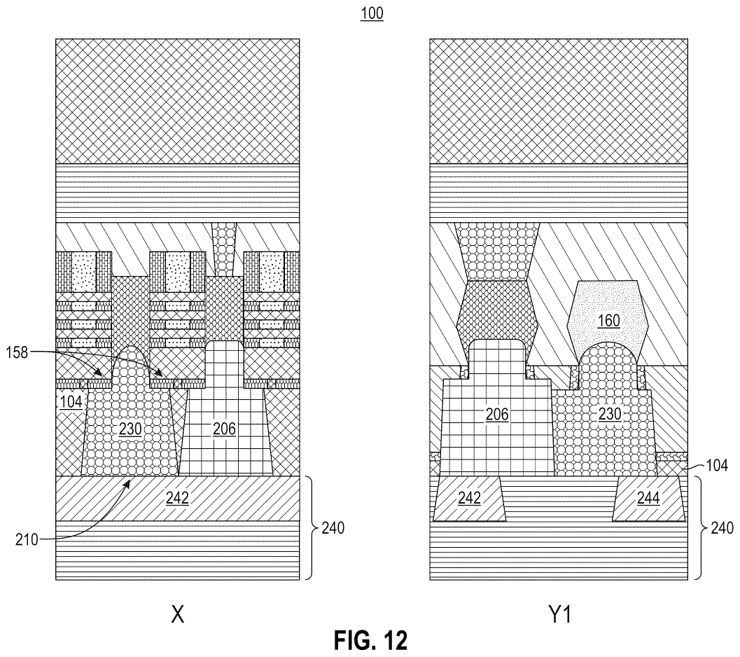

The lower spacers 150 and the inners spacers 152 can be simultaneously formed by ALD or CVD or any other suitable deposition technique that deposits dielectric material within the indents 144. In some examples, the bottom lower spacers 150 and the inners spacers 152 are composed of a dielectric that may additionally serve as a good etch stop layer during the formation of an associated backside contact plug, as depicted in FIG. 10, and/or an associated backside contact as depicted in FIG. 12, such as SiC, SiOC, AlNₓ, HfO, or the like. In other examples, the lower spacers 150 and the inners spacers 152 may be composed of a low-K dielectric material (a material with a lower dielectric constant relative to SiO₂), SiN, SiO, SiBCN, SiOCN, SiCO, etc. or any other suitable dielectric material. In a particular example, the lower spacers 150 and the inners spacers 152 are a relatively different material than that of the STI liner 111 so as to provide etch selectivity therebetween.

In certain implementations, after the formation of the lower spacers 150 and the inners spacers 152, an isotropic etch process may be performed to create outer vertical surfaces of the lower spacers 150 and the inners spacers 152 that align with or are substantially coplanar with the outer vertical surfaces of the associated gate spacers 130 there above.

For clarity, in some examples, such as those depicted in FIG. 1, the lower spacers 150, in and of themselves, may be referred to herein as bottom isolation regions. Alternatively, in other examples, such as those depicted in FIG. 2, the lower spacers 150 may be referred to herein as an outer dielectric and the retained portion of the lowest sacrificial nanolayer 105 may be referred to herein as a central dielectric which, together, may be respective components of the bottom isolation regions. The elements denoted as bottom isolation region 158 may be used herein generically to refer to both examples.

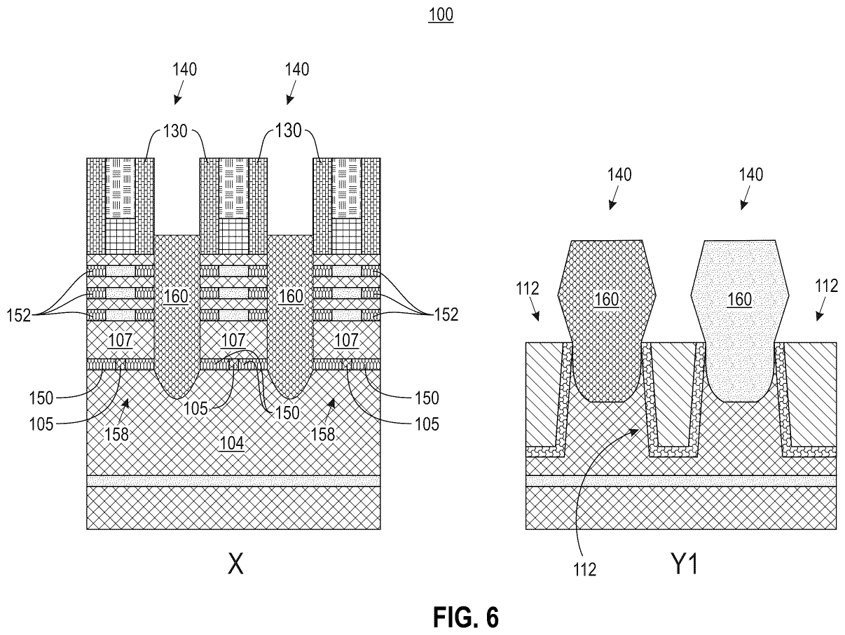

FIG. 6 depicts a cross-sectional view of the semiconductor IC device 100 after fabrication operations, in accordance with embodiments of the present disclosure. In the depicted fabrication stages, a source/drain (S/D) region 160 may be formed within a respective S/D canyon 140.

Each S/D region 160 forms either a source or a drain, respectively, of respective one or more GAA FETs and may be connected to respective end surfaces of active nanolayers 108, may be connected to respective end surfaces (which may also be referred to herein as sidewalls) of inactive nanolayer 107, may be connected to respective end surfaces of inner spacers 152, and may be connected to respective end surfaces of the lower spacers 150.

Each of the S/D region 160 may be composed of a semiconductor material and a dopant. Alternatively, the S/D regions 160 may be composed of a metalloid. As used herein, a “source/drain” region can be a source region or a drain region depending on subsequent wiring and application of voltages during operation of the transistor. When the S/D regions 160 include a semiconductor, the semiconductor material that provides each of the S/D region 160 is composed of one of the semiconductor materials mentioned above for the semiconductor structure 102, the active nanolayers 108, and/or the inactive nanolayer 107.

When the S/D regions 160 include a semiconductor, the dopant that is present in the S/D region 160 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous.

When the S/D regions 160 include a semiconductor, the S/D region(s) 160 may be formed by epitaxially growth within the S/D canyons 140. In some examples, S/D region(s) 160 are formed by in-situ doped epitaxial growth. In some embodiments, the S/D region(s) 160 epitaxial growth may overgrow above the upper surface of the semiconductor IC device 100. In some implementation, all n-type S/D regions 160 may be formed and subsequently all p-type S/D regions 160 may be formed, or vice versa.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors.

When the S/D regions 160 include a semiconductor, in certain implementation, the S/D regions 160 may be epitaxially grown utilizing the respective surfaces of the upper substrate 104, the inactive nanolayer 107, and the active nanolayers 108 that are exposed to the S/D canyons 140 as the seed surface. The presence and vertical thickness of inactive nanolayer 107, relative to the active nanolayers 108, may enable the formation of the S/D regions 160 that are relatively deeper (i.e. have a relatively larger vertical dimension) compared to other GAA FETs that do not include the inactive nanolayer 107.

When the S/D regions 160 include a semiconductor, the S/D region(s) 160 may be overgrown and then partially recessed such that an upper portion of the S/D region(s) 160 are removed. For example, the upper portion of the one or more S/D region(s) 160 may be etched or otherwise removed. The etch may be timed or otherwise controlled to stop the removal of S/D region(s) 160 such that the top surface of S/D region(s) 160 is above the upper surface of the topmost active nanolayer 108 so as to appropriately contact the end surface of the topmost active nanolayer 108.

For clarity, the bottom isolation region(s) 158 and or the inactive nanolayer 107 may enable the absence of a backside contact placeholders underneath the S/D regions 160. For example, a backside contact placeholder need not be formed within the S/D canyons 140 prior to the S/D region(s) 160 being formed.

For clarity, the formation of S/D regions 160 may occur in sequential fabrication stages. For example, when the S/D regions 160 include a semiconductor, S/D regions of a first type (e.g., p-type) may be formed and in a subsequent stage, S/D regions of a second type (e.g., n-type) may be formed, or vice versa. In a particular example, as depicted in the Y1 cross-section, a S/D region 160 of a first type may be adjacent to a S/D region 160 of a second type and separated from such by a STI region 112.

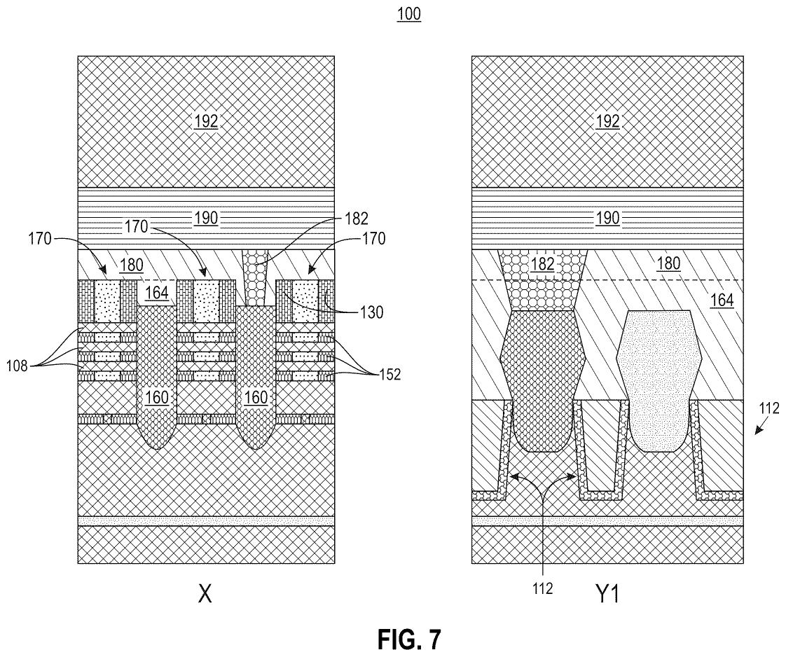

FIG. 7 depicts a cross-sectional view of the semiconductor IC device 100 after fabrication operations, in accordance with embodiments of the present disclosure. In the depicted fabrication stages, interlayer dielectric (ILD) 164 may be formed, the sacrificial gate structures 120 may be removed, the active nanolayers 108 may be released, replacement gate structures 170 may be formed in place of the removed sacrificial gate structures 120, frontside ILD 180 may be formed, one or more frontside contacts 182 may be formed, a frontside back end of the line (BEOL) network 190 may be formed, and a carrier wafer 192 may be bonded thereto.

ILD 164 may be formed upon the one or more source/drain (S/D) regions 160 and upon at least the sidewalls of the sacrificial gate structures 120 and may be further formed upon the STI region(s) 112. The ILD 164 may be formed by depositing a dielectric material, such as, for example, porous silicates, carbon doped oxides, silicon dioxides, silicon nitrides, silicon oxynitrides, or other dielectric materials. Any manner of forming the ILD 164 can be utilized. The ILD 164 can be formed using, for example, CVD, PECVD, ALD, flowable CVD, spin-on dielectrics, or PVD.

In an example, the ILD 164 may be formed to a thickness above the top surface of the sacrificial gate structures 120. Subsequently, a planarization process, such as a CMP, may be performed to remove the sacrificial gate cap 124, to partially remove the excess ILD 164, and to partially remove the gate spacers 130. The planarization may also partially remove some of the sacrificial gate 122 or may at least expose the sacrificial gate 122 of the sacrificial gate structures 120. The CMP may create a planar or horizontal top surface for the semiconductor IC device 100. In other words, the respective top surfaces of ILD 164, gate spacers 130, sacrificial gates 122 may be coplanar.

The sacrificial gate structure 120 may be removed by initially removing the sacrificial gate 122 and sacrificial gate oxide by a removal technique, such as one or more series of etches. For example, such removal may be accomplished by an etching process. Appropriate etchants may be used that remove the sacrificial gate 122 and/or sacrificial gate oxide selective to the active nanolayers 108, gate spacers 130, inner spacers 152, or the like.

The active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, the inactive nanolayer 107, inner spacers 152, gate spacers 130, or the like. After the removal of sacrificial nanolayers 106, void spaces may exist between the active nanolayers 108.

For clarity, the removal of at least the sacrificial gate 122 and the sacrificial nanolayers 106 generally form a replacement gate structure opening. A particular replacement gate structure 170 may be formed around the active nanolayers 108 within one replacement gate structure opening.

Replacement gate structure(s) 170 may be formed by initially forming an interfacial layer (not shown) on the interior surfaces of the gate structure opening (e.g., interior surfaces of gate spacer 130, the interior surfaces of the active nanolayers 108, the interior surfaces of the inactive nanolayer 107, and interior surfaces of inner spacers 152. Then, a high-K layer may be formed to cover the surfaces of exposed surfaces of the interfacial layer. The high-K layer can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-K layer can include a single layer or multiple layers, such as metal layer, liner layer, wetting layer, and adhesion layer.

Replacement gate structure(s) 170 may be further formed by depositing a work function metal (WFM) gate upon the high-κ layer. The WFM gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate can be reduced by chemical-mechanical polishing (CMP) and/or etching. Therefore, the planarization process can be provided by CMP. Other planarization process can include grinding and polishing. In general, the work function metal (WFM) gate sets the threshold voltage (Vt) of the device. The high-K layer separates the WFM gate from the nanolayer channel (i.e., active nanolayers 108). Other metals that may be desired to further fine tune the effective work function (eWF) and/or to achieve a desired resistance value associated with current flow through the gate in the direction parallel to the plane of the nanolayer channel.

The one or more replacement gate structures 170 may be further formed by depositing a conductive fill gate upon the WFM gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 164, gate spacers 130, replacement gate structure(s) 170, may be horizontal and/or may be at least substantially coplanar.

The frontside ILD 180 may be formed upon respective top surfaces of replacement gate structure(s) 170, ILD 164, and gate spacers 130. The frontside ILD 180 may be formed by depositing a dielectric material, such as, for example, porous silicates, carbon doped oxides, silicon dioxides, silicon nitrides, silicon oxynitrides, or other dielectric materials. The material of the frontside ILD 180 may be the same as the material of the ILD 164, as depicted. Alternatively, the frontside ILD 180 may be a relatively different dielectric material than the dielectric material of ILD 164.

The frontside contacts 182 may be formed by patterning respective frontside contact openings within the frontside ILD 180, the frontside ILD 180, respectively, from the frontside (i.e., from above the semiconductor IC device 100, as depicted, downward to respective structures thereof). The frontside contacts 182 may be in direct or indirect physical and electrical contact with respective material(s) of one or more regions of the semiconductor IC device 100.

The frontside contacts 182 may be formed by depositing conductive material such as metal into the respective frontside contact opening(s). In an example, frontside contacts 182 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contacts 182 are fabricated in middle-of-line (MOL) fabrication operations and may be illustrations of MOL contacts.

Further in the depicted fabrication stages, a frontside back end of line (BEOL) network 190 may be formed and a carrier wafer 192 may be bonded to the frontside BEOL network 190. In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

In the present example, there are multiple BEOL levels each on opposites sides of the semiconductor IC device 100. First, a frontside BEOL network 190 is formed on the frontside of the semiconductor device 100. Subsequently, a backside BEOL network 240, as depicted in FIG. 12, may be formed.

In the depicted example, the frontside BEOL network 190 is formed over the frontside ILD 180 and upon the frontside contacts 182. Respective wires within the frontside BEOL network 190 may be electrically connected to the one or more S/D regions 160, to the one or more replacement gate structure(s) 170, or the like, by a respective frontside contacts 182. For example, respective wire(s) within the frontside BEOL network 190 may be electrically connected to an appropriate S/D region 160 by a frontside contact 182 and another and different group of respective wire(s) within the frontside BEOL network 190 may be electrically connected to an appropriate replacement gate structure 170 by a different frontside contact 182, etc.

The frontside BEOL network 190 can include one or more interconnect dielectric material layers (including one of the dielectric materials mentioned above for the frontside ILD 180) and contains conductive wires (the conductive wires can be composed of any electrically conductive material, metal, electrically conductive metal alloy, or the like) embedded therein. In some embodiments, the frontside conductive wires within the frontside BEOL network 190 are composed of Cu. The frontside BEOL network 190 can include “x” numbers of frontside metal levels, wherein “x” is an integer starting from 1. The frontside BEOL network 190 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 100 may be further fabricated by bonding carrier wafer 192 to the frontside BEOL network 190. The carrier wafer 192 can include one of the semiconductor materials mentioned above for the semiconductor structure and the carrier wafer 192 may be attached to the semiconductor IC device 100 by a wafer-to-wafer bonding technique.

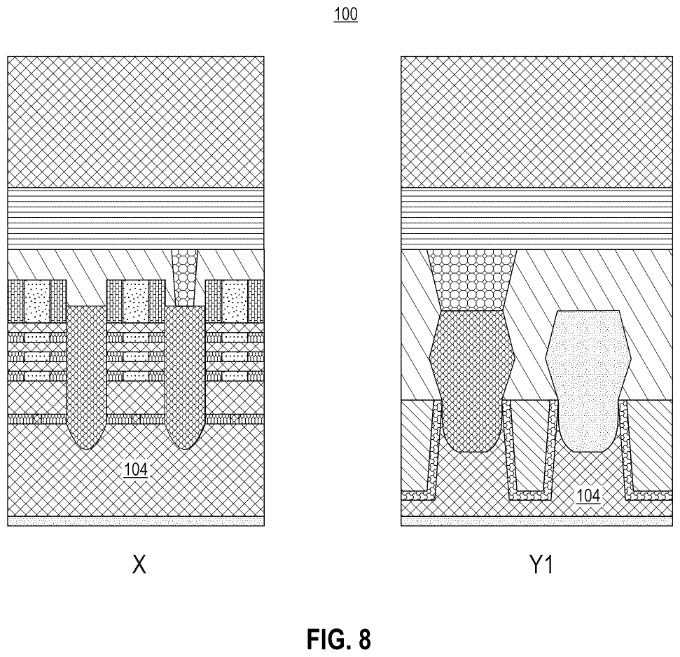

FIG. 8 depicts cross-sectional views of the semiconductor IC device 100 after fabrication operations, in accordance with embodiments of the present disclosure. In the depicted fabrication stages, bottom substrate 101 and etch stop layer 103 may be removed. The bottom substrate 101 may be removed may be recessed by flipping the semiconductor IC device 100 and removing bottom substrate 101 by appropriate substrative removal techniques, such as one or more series of etches. The one or more etches may be timed or otherwise controlled to remove the material of bottom substrate 101 and may utilize the etch stop layer 103 as an etch stop.

The etch stop layer 103 may be removed by appropriate substrative removal techniques, such as one or more series of etches. The one or more etches may be timed or otherwise controlled to remove the material etch stop layer 103 and may utilize the upper substrate 104 as an etch stop. For clarity, semiconductor IC device 100 retains the upper substrate 104 and may utilize the upper substrate 104 to fabricate one or more backside contacts and one or more backside contact plugs therein.

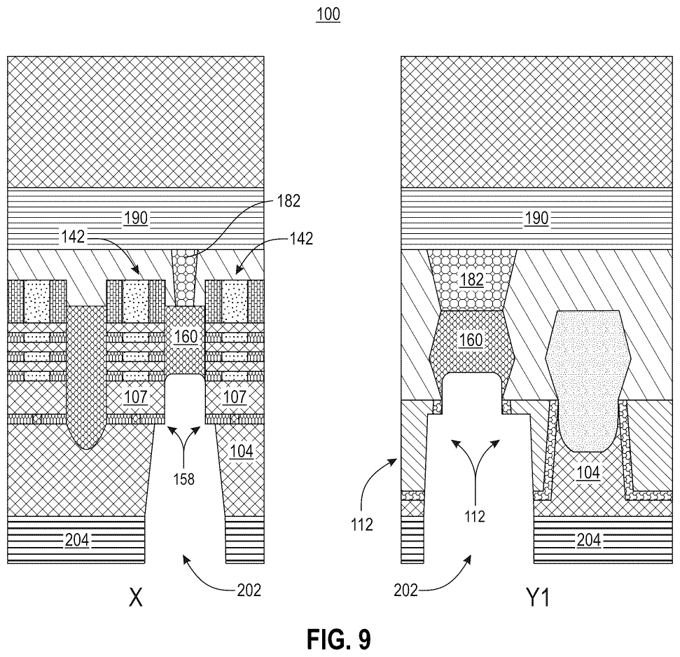

FIG. 9 depicts cross-sectional views of the semiconductor IC device 100 after fabrication operations, in accordance with embodiments of the present disclosure. In the depicted fabrication stages, backside contact plug openings 202 may be formed.

The backside contact plug openings 202 may be formed by lithography and etch process(es). In such process(es), a mask 204 may be applied to the backside of the semiconductor IC device 100 and patterned. Openings in the patterned mask 204 may sequentially expose the portion(s) of the underlying upper substrate 104 portions that are to be removed while other protected portions of semiconductor IC device 100 may be protected and retained. The backside contact plug openings 202 may be located in each and every location in line with a S/D region 160 to which a frontside contact 182 is connected. A respective backside contact plug opening 202 may be formed to expose an associated S/D region 160 there above (e.g., each S/D region 160 that is connected to the frontside BEOL network 190). The backside contact plug opening 202 may have a backside horizontal dimension greater than a similar horizontal dimension of the associated S/D region 160 connected thereto, as depicted.

For clarity, the formation of backside contact plug opening 202 may expose the in line bottom isolation region 158 which may be utilized to mask or effectively protect portions of semiconductor IC device 100 there above, as depicted. Further, backside contact plug opening 202 may expose the end surfaces or sidewalls of the inactive nanolayer 107 within adjacent nanolayers stacks 142. Further, backside contact plug opening 202 may also partially remove adjacent STI regions 112 on either side of the footprint of the S/D region 160 that is associated therewith, as depicted.

The etch that forms the backside contact plug opening 202 may be controlled so that the well surface of the backside contact plug opening 202 is above the inactive nanolayer 107 and below the bottom most active nanolayer 108, as depicted. For clarity, the formation of backside contact plug opening 202 may gouge the backside of the S/D region 160 that is associated therewith, as depicted. As such, the vertical depth of this S/D region 160 may be reduced which may be beneficial when gouged S/D region 160 is a p-type S/D region. Further, the S/D regions 160 of different types within the semiconductor IC device 100 may have relatively different vertical depths, or associated volumes, as illustratively depicted in FIG. 12.

FIG. 10 depicts cross-sectional views of semiconductor IC device 100 shown after illustrative fabrication operation(s), in accordance with one or more embodiments. In the depicted fabrication stage, a respective backside contact plug 206 may be formed within a backside contact plug opening 202 within the retained upper substrate 104.

The backside contact plugs 206 may be formed by depositing a dielectric layer over the backside of the semiconductor IC device 100 and within the backside contact plug openings 202. The backside contact plug 206 can be any suitable dielectric material, such as, for example, porous silicates, carbon doped oxides, silicon dioxides, silicon nitrides, silicon oxynitrides, or other dielectric materials. Subsequently, a planarization process, such as a CMP, may be performed to remove excess backside contact plug 206 material and to expose the upper substrate 104. As a result, the respective bottom surfaces of backside contact plugs 206 and upper substrate 104 may be substantially horizontal and/or substantially coplanar.

For clarity, the material of the backside contact plugs 206 may be a relatively different material compared to upper substrate 104, as depicted. This may be beneficial, for example, in situations where a particular backside contact plug 206 is between adjacent backside contacts and relatively more robust (compared to that in which the material of upper substrate 104 provides) electrical isolation, barrier protection, or the like, between the adjacent backside contacts is desirable. For clarity, the backside contact plug 206 may directly contact the associated S/D region 160, the inactive nanolayers 107, the bottom isolation regions 158, and the upper substrate 104.

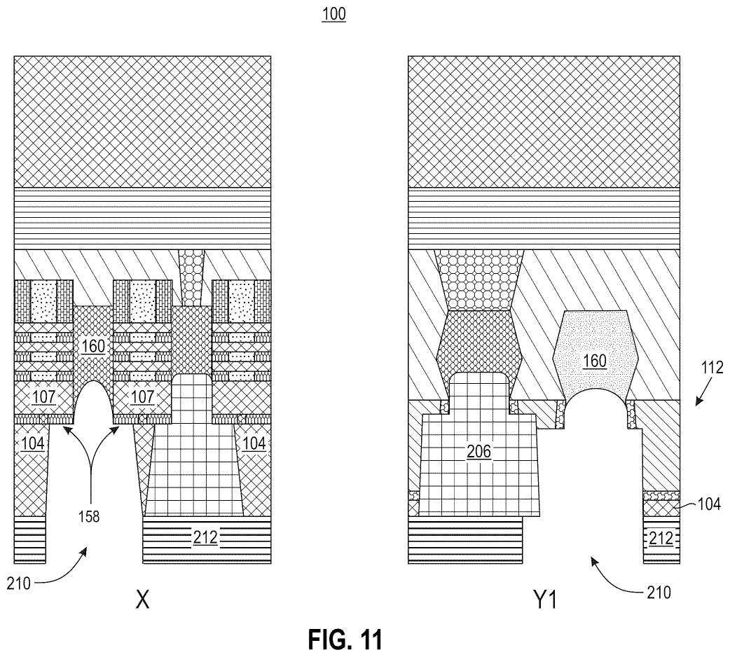

FIG. 11 depicts cross-sectional views of semiconductor IC device 100 shown after illustrative fabrication operation(s), in accordance with one or more embodiments. In the depicted fabrication stage, backside contact openings 210 may be formed.

The backside contact openings 210 may be formed by lithography and etch process(es). In such process(es), a mask 212 may be applied to the backside of the semiconductor IC device 100 and patterned. Openings in the patterned mask 212 may sequentially expose the portion(s) of the underlying upper substrate 104 that are to be removed while other protected portions of semiconductor IC device 100 may be protected and retained. The backside contact opening 210 may be located in line with a particular S/D region 160 in which a frontside contact 180 is not connected.

For clarity, the formation of backside contact opening 210 may expose the in line bottom isolation region 158 which may be utilized to mask or effectively protect portions of semiconductor IC device 100 there above, as depicted. For clarity, the formation of backside contact opening 210 may gouge the backside of the S/D region 160 that is associated therewith, as depicted. The degree or amount of gouging of the associated S/D regions 160 may be substantially the same or relatively different compared to the degree or amount of gouging of S/D regions 160 that are associated with backside contact plug 206. For clarity, the backside surface of the S/D region 160 associated with backside contact opening 210 may be above the bottom surface of the inactive nanolayer 107.

The etch to form the backside contact opening 210 may remove portions of the STI regions 112. For example, the backside contact opening 210 may remove portions of the STI liner 111 and the STI fill 113 that are not protected by the mask 212, as depicted in the Y1 cross-section.

The backside contact opening 210 may be formed to expose the associated S/D region 160 there above. Further, as depicted in the Y1 cross-section, the etch that forms the backside contact openings 210 may be selective to the material of the backside contact plug 206. Therefore, the backside contact opening 210 may be formed to expose a portion of one or more adjacent backside contact plugs 206. The backside contact openings 210 may have a backside horizontal dimension greater than a similar horizontal dimension of the associated S/D region 160 there above, as depicted.

FIG. 12 depicts cross-sectional views of semiconductor IC device 100 shown after illustrative fabrication operation(s), in accordance with one or more embodiments. In the depicted fabrication stage, a backside contact 230 may be formed within a respective backside contact opening 210 and a backside BEOL network 240 may be formed.

The backside contacts 230 may be formed by forming respective backside contacts 230 within a respective backside contact opening 210 against the associated S/D region 160. The backside contacts 230 may be formed by depositing conductive material, such as metal, within the backside contact openings 210. In an example, multiple backside contacts 230 may be simultaneously formed by depositing a liner, such as Ni, NiPt or Ti, etc. onto the backside of semiconductor IC device 100 and into the backside contact openings 210, depositing an adhesion liner, such as TiN, TaN, etc. upon the liner, and by depositing a conductive fill, such as Al, Ru, W, Co, Cu, etc. upon the adhesion liner.

For clarity, because backside contact 230 may be formed within the backside contact opening 210 against S/D region 160, the backside contact 230 may generally take the form of the void thereof. For example, the backside contact 230 may be generally formed within the gouge (if applicable) of the applicable one or more S/D regions 160. For example, the backside contact 230 may be formed within the gouge of the S/D region 160 depicted in the X cross-section. However, in an alternative to that depicted, the S/D region 160 in the Y1 cross-section need not be gouged as this S/D region 160 may have etch selectivity with the upper substrate 104.

For clarity, a first backside contact 230 (illustratively depicted the X cross-section) may be surrounded by the retained upper substrate structure 104 (on the left and right) and the STI regions 112 (in the front and rear). Another backside contact (illustratively depicted in the Y1 cross section) may be surrounded by the same structures and also in contact with at least one backside contact plug 206.

Subsequently, a planarization process, such as a CMP, may expose a bottom surface of the upper substrate 104, the backside contact plugs 206, and the respective bottom surfaces of the backside contacts 230. As a result, the respective bottom surfaces of backside contacts 230, the backside contact plugs 206, and the upper substrate 104 may be substantially horizontal and/or substantially coplanar.

The backside BEOL network 240, such as a backside power distribution network (BSPDN) may be formed upon the backside contacts 230, upon the upper substrate structure 104, upon the backside contact plugs 206, etc. The backside BEOL network 240 may include signal wires for signal routing and power wires for providing power potential (e.g., VDD, VSS, etc.). For example, the backside BEOL network may have a first power wire 242 that may be connected to both a backside contact 230 and the adjacent backside contact plug 206 and a second power wire 244 that may be connected to both a backside contact 230 and am adjacent backside contact plug (not shown).

The backside BEOL network 240 may allow for the distribution of power wires and signal wires between both the frontside and backside of the semiconductor IC device. The backside BEOL network 240 may further allow for the full or partial decoupling of signal routing and/or power routing and/or allows for dividing or splitting power wires and/or signal wires between both the frontside BEOL network 190 and the backside BEOL network 240 of the semiconductor IC device 100. By also incorporating the backside BEOL network 240, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 240 may be electrically connected to the one or more S/D regions 160 by way of a particular backside contact 230. For example, a first backside wire within the backside BEOL network 240 may be electrically connected to one or more different backside contacts 230, or the like.

The backside BEOL network 240 can include one or more interconnect dielectric material layers and contains backside conductive wires and/or interconnects, such as VIAs, embedded therein. In some embodiments, the backside wires within the backside BEOL network 240 are composed of Cu. The backside BEOL network 240 can include “x” numbers of backside metal levels, wherein “x” is an integer starting from 1. If not included in frontside BEOL network 190, backside BEOL network 240 may further contain conductive pads that are connected to one or more of the backside metal wires and may be used to connect the semiconductor IC device 100 to the external and/or higher-level structure.

In an example, signal routing and power routing is effectively split between the frontside BEOL network 190 and the backside BEOL network 240. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

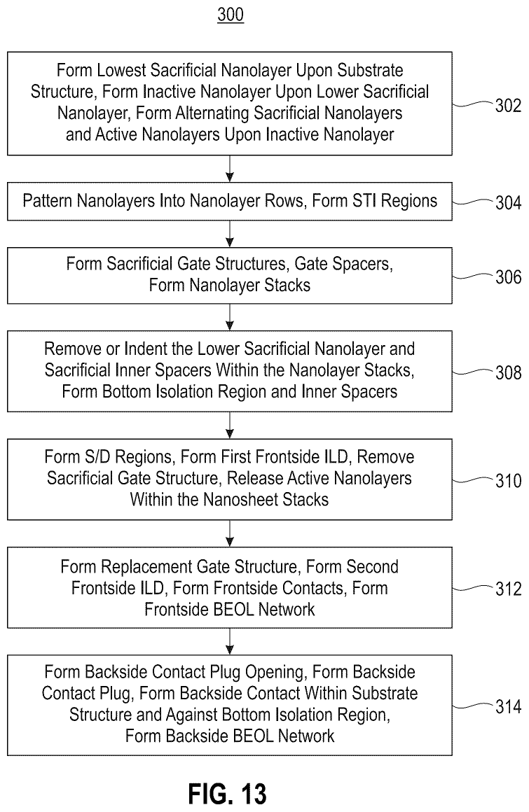

FIG. 13 depicts a flow diagram illustrating method 300 to fabricate a semiconductor IC device, such as semiconductor IC device 100. The depicted fabrication operations of method 300 are illustrated and described above with reference to one or more of FIG. 4 through FIG. 12 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming the lowest sacrificial nanolayer 105 upon the substrate structure 102, with forming the inactive nanolayer 107 upon the lowest sacrificial nanolayer 105, and with forming alternating sacrificial nanolayers 106 and active nanolayers 108 upon the inactive nanolayer 107.

At block 304, method 300 may continue with patterning the nanolayers into nanolayer rows 109 and with forming STI regions 112 between the nanolayer rows 109. At block 306, method may continue with forming sacrificial gate structures 120, with forming gate spacers 130, and with patterning the nanolayer rows 109 into nanolayer stacks 142.

At block 308, method 300 may continue with removing completely, or indenting, the lowest sacrificial layer 105 and indenting the sacrificial nanolayers 106 within the nanolayer stacks 142 and with forming the bottom isolation region 158 within the associated void formed by the partial or full removal of the lowest sacrificial layer 105. Block 308 may also include forming inner spacers 152 within the associated void formed by the partial removal of the sacrificial nanolayers 106. The bottom isolation region 158 may include one or more instances of the lower spacers 150 and a residual portion of the lowest sacrificial layer 105 when the lowest sacrificial layer 105 is not completely removed. The bottom isolation region 158 may include a lower spacer 150 when the lowest sacrificial layer 105 is completely removed.

At block 310, method 300 may continue with forming S/D regions 160, with forming ILD 164, with removing sacrificial gate structures 120, and with releasing the active nanolayers 108 within the nanosheet stacks 142 by removing the sacrificial nanolayers 106.

At block 312, method 300 may continue with forming the respective replacement gate structure 170 within the opening formed by the removal of the sacrificial gate structure 120 and the releasing of the active nanolayers 108. At block 312, method 300 may further continue with forming ILD 180, with forming frontside contacts 182, and with forming frontside BEOL network 190.

At block 314 method 300 may continue with forming one or more backside contact plug openings 202, with forming a backside contact plug 206 within a respective backside contact plug opening 202, with forming backside contacts 230 within the substrate structure 102, and with forming backside BEOL network 240. One or more of the backside contacts 230 may be formed against one or more of the backside contact plugs 206.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a semiconductor base comprising a first sidewall and a second sidewall;
a plurality of channels above the semiconductor base;
a gate upon the semiconductor base and surrounding each of the plurality of channels;
a first source/drain (S/D) region directly connected to the plurality of channels and at least partially to the first sidewall of the semiconductor base;
a second S/D region directly connected to the plurality of channels;
a retained semiconductor substrate structure below the semiconductor base; and
a backside contact plug within the retained semiconductor substrate, the backside contact plug in direct contact with the second S/D region, and in direct contact with the second sidewall of the semiconductor base.

2. The semiconductor IC device of claim 1, wherein the backside contact plug substantially prevents electrical current between the first S/D region and the second S/D region through the semiconductor base.

3. The semiconductor IC device of claim 1, wherein a backside surface of the second S/D region is above a frontside surface of the semiconductor base.

4. The semiconductor IC device of claim 1, further comprising:
a backside contact within the retained semiconductor substrate in direct contact with the first S/D region.

5. The semiconductor IC device of claim 4, wherein a frontside surface of the backside contact plug is above a frontside surface of the backside contact.

6. The semiconductor IC device of claim 1, wherein the plurality of channels are directly connected to the second S/D region.

7. The semiconductor IC device of claim 5, further comprising:
a backside back end of line (BEOL) network directly connected to the backside contact, directly connected to the backside contact plug, and directly connected to the retained semiconductor substrate structure.

8. The semiconductor IC device of claim 1, further comprising:
a frontside contact directly connected to the second S/D region.

9. The semiconductor IC device of claim 8, further comprising:
a frontside back end of line (BEOL) network directly connected to the frontside contact.

10. The semiconductor IC device of claim 1, further comprising:
a bottom isolation region between the semiconductor base and the retained semiconductor structure.

11. The semiconductor IC device of claim 4, further comprising:
a bottom isolation region directly connected to a backside of the semiconductor base and directly connected to the backside contact.

12. A semiconductor integrated circuit (IC) device comprising:
a first transistor comprising a semiconductor base, a plurality of channels above the semiconductor base, a gate upon the semiconductor base and surrounding each of the plurality of channels, a first source/drain (S/D) region, and a second S/D region;
a second transistor comprising a third S/D region adjacent to the second S/D region;
a retained semiconductor substrate structure below the semiconductor base;
a first backside contact within the retained semiconductor substrate in direct contact with the first S/D region;
a backside contact plug within the retained semiconductor substrate and in direct contact with the second S/D region; and
a second backside contact within the retained semiconductor substrate in direct contact with the third S/D region and in direct contact with the backside contact plug.

13. The semiconductor IC device of claim 12, wherein the backside contact plug substantially prevents electrical current between the first S/D region and the second S/D region through the semiconductor base.

14. The semiconductor IC device of claim 12, wherein a backside surface of the second S/D region is above a frontside surface of the semiconductor base.

15. The semiconductor IC device of claim 12, wherein a frontside surface of the backside contact plug is above a frontside surface of the first backside contact and is above a frontside surface of the second backside contact.

16. The semiconductor IC device of claim 12, further comprising:
a backside back end of line (BEOL) network directly connected to the first backside contact, directly connected to the second backside contact, directly connected to the backside contact plug, and directly connected to the retained semiconductor substrate structure.

17. The semiconductor IC device of claim 12, further comprising:
a frontside contact directly connected to the second S/D region.

18. The semiconductor IC device of claim 17, further comprising:
a frontside back end of line (BEOL) network directly connected to the frontside contact.

19. The semiconductor IC device of claim 1, further comprising:
a bottom isolation region between the semiconductor base and the retained semiconductor structure.

20. A semiconductor integrated circuit (IC) device comprising:
a semiconductor base;
a source/drain (S/D) region directly connected to a plurality of channels and directly connected to a portion of a first sidewall of the semiconductor base;
a backside contact directly connected to the S/D region and directly connected to a remaining portion of the first sidewall of the semiconductor base;
a backside contact plug directly connected to a second sidewall of semiconductor base; and
wherein the backside contact plug substantially prevents electrical current from the S/D region through the semiconductor base.
